(19) United States
(12) Patent Application Publication
(10) Pub. No.: US 2021/0320600 A1
(43) Pub. Date: Oct. 14, 2021

(54) Stepper Motor Driver With Brake Drive, Driver Device And Automation Device

(71) Applicant: CHINA LEADSHINE TECHNOLOGY CO., LTD., Shenzhen, Guangdong (CN)

(72) Inventors: Zhouyong Zhu, Shenzhen, Guangdong (CN); Jun Qin, Shenzhen, Guangdong (CN); Jianhua Lin, Shenzhen, Guangdong (CN); Weiping Li, Shenzhen, Guangdong (CN); Tiansheng Tian, Shenzhen, Guangdong (CN)

(73) Assignee: CHINA LEADSHINE TECHNOLOGY CO., LTD., Shenzhen, Guangdong (CN)

(21) Appl. No.: 17/271,395

(22) PCT Filed: Sep. 17, 2019
(86) PCT No.: PCT/CN2019/106203

§ 371 Date: Feb. 25, 2021

(30) Foreign Application Priority Data
Sep. 17, 2018 (CN) 201811084261.0

(51) Int. Cl. H02P 8/24; H02P 8/36

(52) U.S. Cl. CPC H02P 8/24; H02P 8/36

(57) ABSTRACT

A stepper motor driver with brake drive, a drive device and an automation device are disclosed. The stepper motor driver comprises a microprocessor (1) embedded with a communication protocol, an external interface unit (3) mutually connected to the microprocessor (1) and a communication interface circuit (2); the microprocessor (1) is also connected to a drive control circuit (4) and a brake device (5), and the brake device (5) is mutually connected to the external interface unit (3); the microprocessor (1) is also mutually connected to a power supply circuit (13) that provides a stable power supply voltage. The stepper motor driver has such advantages as simple structure, high capacity to resist interference, high effectiveness, low cost, and ease in maintenance.

### TECHNICAL FIELD

The present invention involves the field of motor drive technology, particularly involving a stepper motor driver with brake drive, drive device and automation device.

### BACKGROUND ART

After the power supply of a normal stepper motor is cut off, the motor shaft will loosen up; if the motor shaft still needs to be maintained as locked when the power supply is cut off, a brake device needs to be installed additionally at the end of the normal stepper motor. As such, the motor automatically locks when the driver is powered on, and at the same time, the brake loosens up; after the power of the driver is cut off, the brake works instantly to ensure that the motor shaft does not loosen up. Such brake motors are generally applied on the vertical Z axis.

In the prior art, the brake device is generally composed of three parts—the external power supply, the special brake control circuit and the trunk relay. The external power supply is generally 12/24V and the driving current is also around 200 mA to 400 mA, based on the different sizes of the adapter motor; the special brake control circuit is internally provided by the driver and the wires need to be connected through the external interface of the driver during use. At present, stepper motor drivers on the market cannot work without all three above parts, wiring is troublesome for users and the interference and cost are high, and hindering increase in production efficiency; secondly, the control logic is too simple and only involves two modes, namely on and off. The brake continues to emit heat when it works and has low energy efficiency.

### SUMMARY OF INVENTION

### Technical Problem

The present invention resolves the technical issues by providing a stepper motor driver with brake drive, drive device and automation device that has a simple structure, high effectiveness and low cost.

### Solution to Problem

### Technical Solution

In order to solve the above problems, the invention provides a stepper motor driver with brake holding drive,wherein it comprises a microprocessor embedded with a communication protocol, an external interface unit mutually connected to the said microprocessor and a communication interface circuit; the said microprocessor is also connected to a drive control circuit and brake device, and the said brake device is mutually connected to the said external interface unit; the said microprocessor is also mutually connected to a power supply circuit that provides a stable power supply voltage.

Optionally,wherein the said brake device comprises a brake drive circuit and brake; the said brake drive circuit comprises an isolation unit and amplifier, the said micro-processor is connected to the said amplifier through the said isolation unit and the said amplifier is used to amplify the current signal output by the said isolation unit, sending it to the said brake.

Optionally,wherein the said isolation unit, the said amplifier and the said micro-processor are installed on the same circuit board.

Optionally,wherein the said brake drive circuit also comprises a switch unit and the said switch unit is connected in series to the said amplifier.

Optionally,wherein the said brake drive circuit also comprises: a protection unit. One end of the said protection unit is connected to the said amplifier and the other end is connected to the input end of the power supply of the said brake.

Optionally,wherein the said external interface comprises a power supply interface unit, winding interface unit, and I/O interface unit; the said power supply interface unit is mutually connected to the said power supply circuit; one end of the said winding interface unit is mutually connected to the said drive control circuit and the other end is mutually connected to the stepper motor; the said I/O interface unit is mutually connected to the said microprocessor.

Optionally, wherein the said I/O interface unit comprises: the first output interface, the second output interface, and the third output interface; the said first output interface is used to connect to the first end of the said brake, the said second output interface is used to connect to the second end of the brake, and the said third output interface is used to connect to the power ground of the said brake.

Optionally, wherein the said communication interface circuit comprises a physical layer communication circuit and anti-jamming circuit. The said anti-jamming circuit is electrically connected to the said microprocessor through the said physical layer communication circuit.

Optionally,wherein the said anti-jamming circuit comprises the first common mode inductor and first transient voltage suppressor. The said first transient voltage suppressor is connected to one end of the said first common mode inductor.

Optionally, wherein the said anti-jamming circuit is connected to the first transformer. The said first transformer is electrically connected to the said first common mode inductor and the said first transformer is used to send the signal sent from the said first common mode inductor to the said microprocessor.

Optionally,wherein the said stepper motor driver with brake drive also comprises a communication address setting circuit, and the said communication address setting circuit is mutually connected to the said microprocessor; of which, the said communication address setting circuit is a DIP switch.

Optionally, wherein the said stepper motor driver with brake drive also comprises a display unit and the said display unit is electrically connected to the said micro-processor; of which, the said display unit comprises one or several of the following types: LED indicator light, digital tube and liquid crystal display.

Optionally, wherein the said stepper motor driver with brake drive also comprises an alarm unit, and the said alarm unit is electrically connected to the said microprocessor.

In order to solve the above problems, the invention provides a drive device, comprising a motor, wherein the said drive device comprises the stepper motor driver with brake drive as described above.

In order to solve the above problems, the invention provides an automation device, wherein it comprises the drive device as described above.

### Advantageous Effects of Invention

### Advantageous Effects

The stepper motor driver with brake drive provided by the present invention comprises: a microprocessor embedded with a communication protocol, an external interface unit mutually connected to the microprocessor and a communication interface circuit;

the microprocessor is also connected to the drive control circuit, communication address setting circuit and brake device, and the brake device is mutually connected to the external interface unit; the microprocessor is also mutually connected to the power supply circuit that provides a stable power supply voltage; the advantages of this module-based circuit design are its simple structure, high capacity of resisting interference, high effectiveness, low cost, and easy to maintain, making it especially marketable;

In addition, as compared to the “control circuit+trunk relay+brake” solution in the prior art, the present invention also has the following advantages: 1) eliminates the need for a trunk relay, where “control circuit+brake” will do, hence, the structure is simple and the cost is low; 2) less wiring by the user, which reduces the difficulty in maintenance; 3) the control circuit is integrated into a free wheel diode, which greatly reduces the interference from the inductive device switch; 4) reduces costs; 5) the addition of PWM control to the brake greatly reduces the working current of the brake, thereby greatly reducing its heat emission, making it effective and environmentally friendly.

### BRIEF DESCRIPTION OF DRAWINGS

### DESCRIPTION OF DRAWINGS

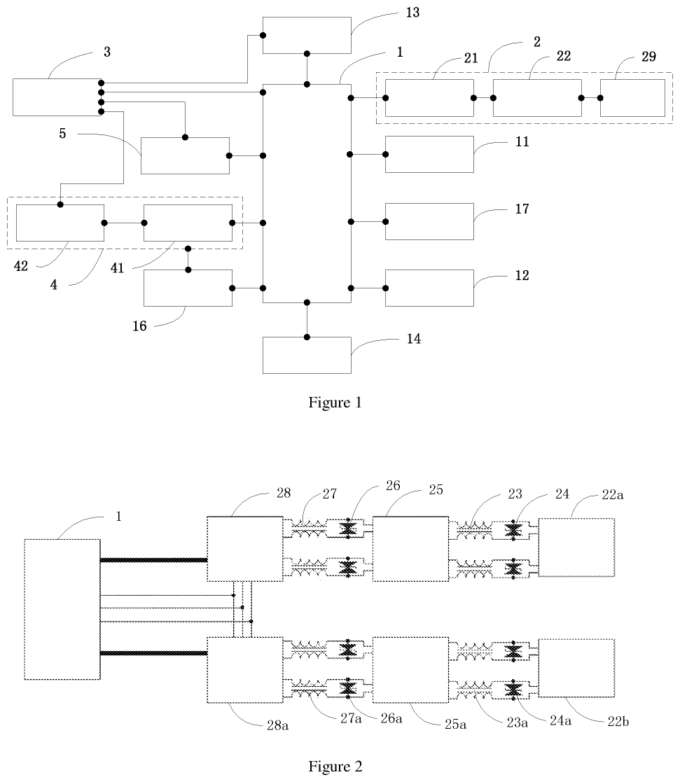

FIG. 1 is the principle block-diagram of the preferred embodiment of the stepper motor driver with brake drive of the embodiment of the present invention;

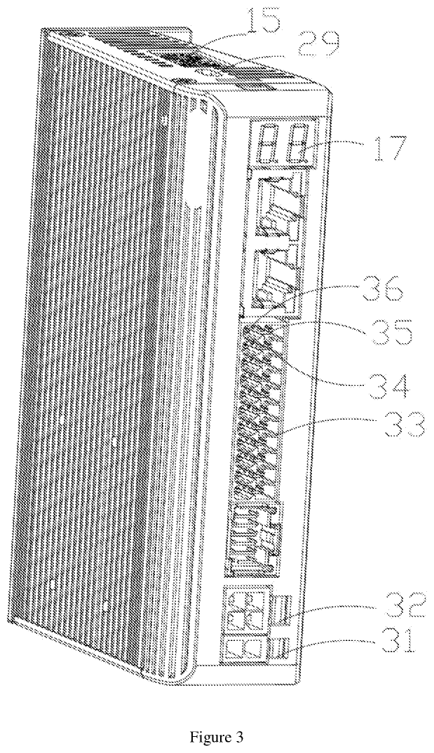

FIG. 2 is the principle block-diagram of part of the circuit of the stepper motor driver with brake drive of the embodiment of the present invention as shown in FIG. 1;

FIG. 3 is the schematic diagram of part of the structure of the stepper motor driver with brake drive of the embodiment of the present invention as shown in FIG. 1;

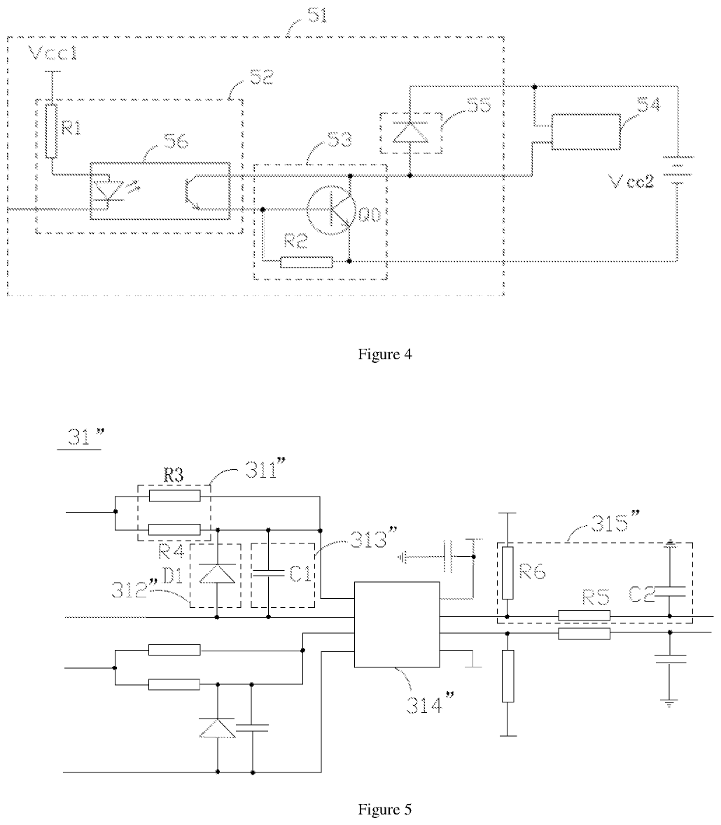

FIG. 4 is the circuit diagram of the connection between the brake device of the stepper motor driver with brake drive and the external power supply of the embodiment of the present invention as shown in FIG. 1;

FIG. 5 is the high-speed differential input signal processing circuit diagram of the stepper motor driver with brake drive of the embodiment of the present invention as shown in FIG. 1;

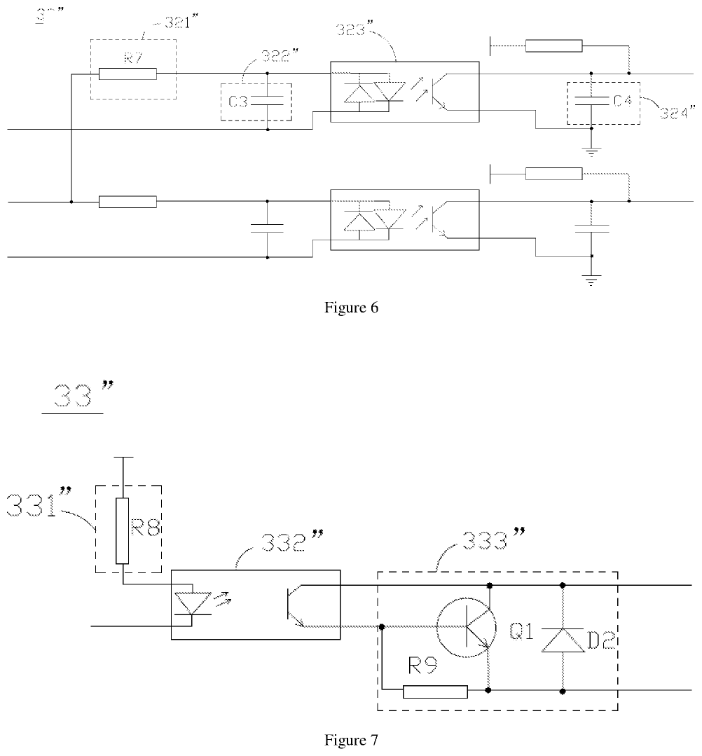

FIG. 6 is the low-speed signal input processing circuit diagram of the stepper motor driver with brake drive of the embodiment of the present invention as shown in FIG. 1;

FIG. 7 is the low-speed differential output signal processing circuit diagram of the stepper motor driver with brake drive of the embodiment of the present invention as shown in FIG. 1;

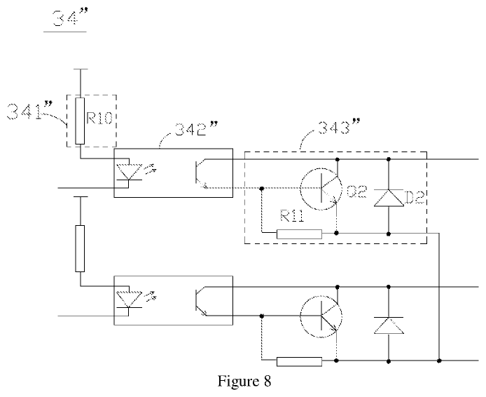

FIG. 8 is the low-speed single-ended output signal processing circuit diagram of the stepper motor driver with brake drive of the embodiment of the present invention as shown in FIG. 1.

### MODE FOR THE INVENTION

### Mode for Invention

The various characteristics and exemplary embodiments of the present invention shall be described in detail below and the present invention shall be described in further detail below with reference to drawings and embodiments to make the purpose, the technical solution and advantages of the present invention clearer and easier to understand. It must be noted here that the description of these embodiment methods is to facilitate an understanding of the present invention and does not constitute restrictions on the present invention. In addition, the technical characteristics involved in the various embodiment methods of the present invention that are described below can be combined together as long as they do not give rise to conflict.

Please refer to FIG. 1 and FIG. 3. This Embodiment disclosed a stepper motor driver with brake drive (hereinafter referred to as stepper motor driver), wherein it comprises a microprocessor 1 embedded with a communication protocol, an external interface unit 3 mutually connected to the said microprocessor 1 and a communication interface circuit 2; the said microprocessor 1 is also connected to the drive control circuit 4, communication address setting circuit 11 and brake device 5, the said brake device 5 is mutually connected to the said external interface unit 3; the said microprocessor 1 is also mutually connected to the power supply circuit 13 that provides a stable power supply voltage. Therefore, the stepper motor driver with brake drive has the advantage of having many functions; at the same time, its module-based circuit design reduces difficulty in maintenance and it is especially marketable.

Optionally, the stepper motor driver also comprises an encoder feedback circuit 14. The encoder feedback circuit 14 is mutually connected to the microprocessor 1 and is used to obtain the encoder signal of the stepper motor and send feedback of the location information to the stepper motor driver in real time for the stepper motor to correct its actions.

Optionally, the communication address setting circuit 11 is a DIP switch unit 15 and the DIP switch unit 15 is mutually connected to the microprocessor 1; it is used to set the parameters of the stepper motor driver, making it more convenient for users to use. Preferably, the DIP switch unit 15 is a rotary DIP switch or smooth DIP switch unit. It can be understood that the quantity of rotary DIP switches may be set as needed, and this is not specifically defined here.

Optionally, the stepper motor driver also comprises an overcurrent protection circuit 16. One end of the overcurrent protection circuit 16 is connected to the microprocessor 1 and the other end is electrically connected to the drive control circuit 4. The drive control circuit 4 is better protected through the overcurrent protection circuit 16 so as to prevent it from being burnt out by overcurrent. Therefore, the stepper motor driver has such advantages as stable operation and long service life. In this Embodiment, the drive control circuit 4 comprises a drive chip 41 and inverter bridge circuit 42. The drive chip 41 is mutually connected to the microprocessor 1 and the drive chip 41 is mutually connected to the winding interface unit 32 of the external interface unit 3 through the inverter bridge circuit 42.

Optionally, the stepper motor driver also comprises a display unit 17. The display unit 17 is electrically connected to the microprocessor 1; of which, the display unit 17 comprises one or several of the following types: LED indicator light, digital tube and liquid crystal display. This is to facilitate parameter setting of the stepper motor driver and the display of the relevant mode and parameters. Therefore, the stepper motor driver has the advantage of being easy to operate.

Optionally, the stepper motor driver also comprises an alarm unit 12, and the said alarm unit 12 is electrically connected to the said microprocessor 1. This is to facilitate the output of the alarm signal when the stepper motor driver is not functioning normally.

Optionally, the communication interface circuit 2 comprises:

The physical layer communication circuit 21. The communication circuit 2 is mutually connected to the microprocessor 1 through the physical layer communication circuit 21.

The anti-jamming circuit 22. The anti-jamming circuit 22 is electrically connected to the microprocessor 1 through the physical layer communication circuit 21.

The USB interface 29. The USB interface 29 is mutually connected to the microprocessor 1 and is used to debug parameters.

Therefore, the stepper motor driver has such advantages as high capacity to resist interference and ease of debugging.

Please refer to FIG. 2. The anti-jamming circuit 22 comprises the first common mode inductor 23 and the first transient voltage suppressor 24. The first end of the first transient voltage suppressor 24 is connected to the first end of the said first common mode inductor 23. The second end of the first transient voltage suppressor 24 is connected to the information input socket 22a and the information input socket 22a is the input interface of communication signals. Optionally, the information input socket 22a may be a RJ45; RJ45 is a type of information socket (that is, the communication terminal) connector of the wiring system. The first transient voltage suppressor 24 has an extremely fast response time (sub-nanosecond level) and a relatively high surge absorption capacity. When both of its ends are subject to transient high-energy impact, the first transient voltage suppressor 24 is able to convert the resistance between the two ends from high impedance to low impedance at a very high speed in order to absorb the transient large current and clamp the voltage of both of it ends at a pre-set value, thereby protecting the circuit components behind from being impacted by the spike in transient high voltage. The first common mode inductor 23 is used to filter the electromagnetic interference signals of the common mode. At the same time, it acts as an EMI filter and it is used to suppress the outward radiation emission of electromagnetic waves produced by the high-speed signal line. Therefore, the stepper motor driver has the advantage of high capacity to resist interference.

Optionally, the anti-jamming circuit 22 is connected to the first transformer 25. The first end of the first transformer 25 is electrically connected to the first common mode inductor 23 and the first transformer 25 is used to send the signal coming from the first common mode inductor 23 to the microprocessor 1.

Optionally, the anti-jamming circuit 22 also comprises the second transient voltage suppressor 26 and the second common mode inductor 27. The second end of the first transformer 25 is electrically connected to the first end of the second transient voltage suppressor 26. The second end of the second transient voltage suppressor 26 is electrically connected to the first end of the second common mode inductor 27 and the second end of the second common mode inductor 27 is electrically connected to the microprocessor 1 through the first physical layer port 28. Therefore, the stepper motor driver has the advantage of high capacity to resist interference.

Optionally, the anti-jamming circuit 22 also comprises the third common mode inductor 23a and the third transient voltage suppressor 24a . The first end of the third transient voltage suppressor 24a is mutually connected to the first end of the third common mode inductor 23a and the second end of the third transient voltage suppressor 24a is mutually connected to the information output socket 22b . The information output socket 22b is the output interface of communication signals. Specifically, the information output socket 22b is a RJ45. The third transient voltage suppressor 24a has an extremely fast response time (sub-nanosecond level) and a relatively high surge absorption capacity. When both of its ends are subject to transient high-energy impact, the third transient voltage suppressor 24a is able to convert the resistance between the two ends from high impedance to low impedance at a very high speed in order to absorb the transient large current and clamp the voltage of both of its ends at a pre-set value, thereby protecting the circuit components behind from being impacted by the spike in transient high voltage. The third common mode inductor 23a is used to filter the common mode electromagnetic interference signal. At the same time, it acts as an EMI filter and it is used to suppress the outward radiation emission of electromagnetic waves produced by the high-speed signal line. Therefore, the stepper motor driver has the advantage of high capacity to resist interference.

Optionally, the anti-jamming circuit 22 is connected to the second transformer 25a. The first end of the second transformer 25a is electrically connected to the third common mode inductor 23a and the second transformer 25a is used to send the signal coming from the third common mode inductor 23a to the microprocessor 1.

Optionally, the anti-jamming circuit 22 also comprises the fourth transient voltage suppressor 26a and the fourth common mode inductor 27a . The second end of the second transformer 25a is electrically connected to the first end of the fourth transient voltage suppressor 26a , the second end of the fourth transient voltage suppressor 26a is electrically connected to the first end of the fourth common mode inductor 27a and the second end of the fourth common mode inductor 27a is electrically connected to the microprocessor 1 through the second physical layer port 28a . Therefore, the stepper motor driver has the advantage of high capacity to resist interference.

Please refer to FIG. 3 and FIG. 4. The external interface unit 3 comprises the power supply interface unit 31, winding interface unit 32, and I/O interface unit 33; the power supply interface unit 31 is mutually connected to the power supply circuit 13;

one end of the winding interface unit 32 is mutually connected to the drive control circuit 4 and the other end is mutually connected to the stepper motor and works as a stepper motor driver; the I/O interface unit 33 is mutually connected to the microprocessor 1 and can input or output various signals.

Optionally, the I/O interface unit 33 comprises: the first output interface 34, the second output interface 35 and the third output interface 36; the first output interface 34 is used to connect to the first end of the brake 54, to connect to the power supply input end of the brake 54, the second output interface 35 is used to connect to the second end of the brake 54, and the third output interface 36 is used to connect to the power ground of the brake 54. Setting the first output interface 34, the second output interface 35 and the third output interface 36 makes it easier to connect to the brake 54, making it easier to use.

Please refer to FIG. 4. The brake device 5 comprises the brake drive circuit 51 and the brake 54. Of which, the brake drive circuit 51 comprises the isolation unit 52 and amplifier 53. The microprocessor 1 is connected to the amplifier 53 through the isolation unit 52 and the amplifier 53 is used to amplify the current signal output by the isolation unit 52 to the brake 54. Driving the brake 54 directly through the brake drive circuit 51 eliminates the need for the traditional trunk relay and reduces the user's labor cost of wiring and the cost of the relay;

Optionally, the isolation unit 52, amplifier 53 and microprocessor 1 are installed on the same circuit board. Therefore, the stepper motor driver has such advantages as simple and compact functional structure, high capacity to resist interference, and ease of use and low-cost.

In this Embodiment, the isolation unit 52 comprises the optoelectronic coupler 56 and the first resistor R1. The anode of the light-emitting diode of the optoelectronic coupler 56 is electrically connected to the first end of the first resistor R1, the cathode of the light-emitting diode of the optoelectronic coupler 56 is electrically connected to the microprocessor 1 and the second end of the first resistor R1 is electrically connected to the power supply Vcc 1. The collector and emitter electrodes of the phototransistor of the optoelectronic coupler 56 are electrically connected to the amplifier 53. The optoelectronic coupler 56 has such advantages as fast response speed, arbitrary adjustment of duty ratio and high capacity to resist interference, so it can increase the response speed and capacity to resist interference of the brake device 5 of this Em bodiment. In addition, the optoelectronic coupler 56 is a current-type device and it can effectively suppress voltage noise. In one embodiment, the phototransistor of the optoelectronic coupler 56 can be replaced with a photodiode. Therefore, the structure of the isolation unit 52 is not specifically defined here, as long as it can be controlled by the microprocessor 1 and can control the amplifier 53.

The amplifier circuit 53 comprises the signal-amplifying triode Q0 and the second resistor R2.

The base electrode of the signal-amplifying triode Q0 is electrically connected to the emitter electrode of the phototransistor, the collector electrode of the signal-amplifying triode Q0 is electrically connected to the collector electrode of the phototransistor, the collector electrode of the signal-amplifying triode Q0 is electrically connected to the second output interface 35, the collector electrode of the signal-amplifying triode Q0 is connected to the first output interface 34 through the protection unit 55 and the first output interface 34 is electrically connected to the external power supply Vcc2. The emitter electrode of the signal-amplifying triode Q0 is grounded. The collector electrode of the signal-amplifying triode Q0 is also electrically connected to the internal coils of the brake 54. In this Embodiment, the amplifier 53 can also be used as the switch circuit to control the output of the current signal to the brake 54. The first end of the second resistor R2 is electrically connected to the base electrode of the signal-amplifying triode Q0 and the second end of the second resistor R2 is electrically connected to the emitter electrode of the signal-amplifying triode Q0. The emitter electrode of the signal-amplifying triode Q0 is connected to the cathode of the external power supply Vcc2 through the third output interface 36. The amplifier 53 of this Embodiment has such advantages as simple structure and high reliability. In one embodiment, amplifier 53 comprises: a triode, MOSFET transistor or insulated gate bipolar transistor (IGBT), that is, the signal-amplifying triode Q0 can be replaced with a MOSFET transistor or IGBT. Therefore, the structure of the amplifier 53 is not specifically defined here.

The brake device 5 also comprises a protection unit 55. One end of the protection unit 55 is connected to the amplifier 53 and the other end is connected to the power supply input end of the brake 54. The internal coils of the brake 54 are an inductive device and inductive devices have relatively large dv/dt (voltage rise rate) during power on/off, which interferes with the reception of commands by the driver and even the normal operations of the entire system. Therefore, the installation of the protection unit 55 may increase the capacity of the brake device 5 to resist interference. In this Embodiment, the protection unit 55 is a diode and the diode is set up on the circuit board. The anode of the diode is mutually connected to the collector electrode of the signal-amplifying triode Q0 and the cathode of the diode is electrically connected to the power supply input end connected to the brake 54. In one embodiment, the protection unit 55 comprises: a network composing of a diode or resistor and capacitor. Therefore, the structure of the protection unit 55 is not specifically defined here. The protection unit 55 of this Embodiment has such advantages as simple structure and high reliabilities.

When being powered on, the microprocessor 1 outputs a low level signal to drive the isolation unit 52 to turn on. The light-emitting diode of the isolation unit 52 emits light and the phototransistor transmits, driving the amplifier 53 of the isolation unit 52 to function, that is, the signal-amplifying triode Q0 transmits and current passes through the internal coils of the brake 54. The magnetic field produced by the coils' current renders the motor shaft to be in a free state. When the power supply is cut off, the microprocessor 1 outputs a high level signal, the light-emitting diode is extinguished and the isolation unit 52 turns off. The signal-amplifying triode Q0 stops and no current passes through the internal coils of the brake 54, so the brake 54 is in a normally closed state and the motor shaft is in a locked state.

In conclusion, this Embodiment has the following beneficial effects: As the stepper motor driver of this Embodiment uses a module-based circuit design, it reduces the difficulty in maintenance and has such advantages as simple structure, high effectiveness, high capacity to resist interference and low cost, so it especially is marketable. In addition, this solution at least possesses the following characteristics as compared to the “control circuit+trunk relay+brake” solution in the prior art:

1. Eliminates the need for a trunk relay where “control circuit+brake” will do, so the structure is simple and the cost is low;

2. Less wiring by the user, which reduces difficulty in maintenance;

3. The control circuit is integrated into a free wheel diode, which greatly reduces the interference from the inductive device switch;

4. Reduces costs;

5. The addition of PWM control to the brake greatly reduces the working current of the brake, thereby greatly reducing its heat emission and it is highly effective and environmentally friendly.

The structure of this Embodiment is similar to Embodiment 1, with the difference being: The brake device 5 also comprises a switch unit (not shown in the figure) and the switch unit is connected in series to the amplifier 53. In this Embodiment, the switch unit is a transistor switch and the transistor switch is electrically connected to the microprocessor 1. When the microprocessor 1 drives the isolation unit 52 to turn on, the microprocessor 1 simultaneously drives the switch unit to turn on. When the microprocessor 1 controls the isolation unit 52 to turn off, the microprocessor 1 simultaneously controls the switch unit to turn off, thereby increasing the reliability of the brake device 5. Of which, the transistor switch can comprise a silicon-controlled resistor or field-effect transistor. Of course, it can also be another type of switch, so its structure is not specifically defined here.

The structure of this Embodiment is similar to Embodiment 1, with the difference being: the microprocessor 1 of this Embodiment is an ARM chip of an EtherCAT slave controller, so the signal processing speed is fast and it is highly efficient. Of course, the microprocessor 1 may also be a DSP chip. A single ARM processing chip or single DSP chip is preferred for the microprocessor of this Embodiment. This better simplifies the circuit structure as compared to the prior art, where it generally uses the architecture of two processor modules. In addition, using the EtherCAT communication protocol can improve the processing efficiency.

Please refer to FIGS. 5 to 8. The structure of this Embodiment is similar to Embodiment 1, with the difference being: the stepper motor driver also comprises a highspeed differential input signal processing circuit 31″, low-speed signal input processing circuit 32″, low-speed differential output signal processing circuit 33″ and low-speed single-ended output signal processing circuit 34″. In this Embodiment, the high-speed differential input signal processing circuit 31″ comprises the first current-limiting unit 311″, anti-reverse connection unit 312″, first filter unit 313″, first high-speed signal isolation unit 314″ and the second filter unit 315″.

The first current-limiting unit 311″ and the anti-reverse connection unit 312″ are electrically connected to the first filter unit 313″, and the first high-speed signal isolation unit 314″ and the first filter unit 313″ are electrically connected to the second filter unit 315″. In this Embodiment, there are two first current-limiting units 311″. Each of the first current-limiting unit 311″ comprises the third resistor R3 and fourth resistor R4 that are connected in parallel. The first end of the third resistor R3 and the first end of the fourth resistor R4 are electrically connected to the I/O interface unit 33. The second end of the third resistor R3 and the second end of the fourth resistor R4 are connected to the first high-speed signal isolation unit 314″.

The anti-reverse connection unit 312″ comprises the first diode D1. The anode of the first diode D1 is electrically connected to the I/O interface unit 33 and the cathode of the first diode D1 is mutually connected to the fourth resistor R4. The first filter unit 313″ comprises the first capacitor C1 and the first capacitor C1 is connected in parallel to the first diode D1. The second filter unit 315″ comprises the second capacitor C2, the fifth resistor R5 and sixth resistor R4. The first end of the fifth resistor R5 is electrically connected to the first high-speed signal isolation unit 314″, the second end of the fifth resistor R5 is electrically connected to the microprocessor, the first end of the sixth resistor R4 is mutually connected to the first end of the fifth resistor R5, the first end of the second capacitor C2 is mutually connected to the second end of the fifth resistor R5 and the second end of the second capacitor C2 is grounded. The high-speed differential input signal processing circuit 31″ of this Embodiment has such advantages as simple structure and stable and reliable signal transmission.

The low-speed signal input processing circuit 32″ comprises the second current-limiting unit 321″, the third filter unit 322″, the second isolation unit 323″ and the fourth filter unit 324″. The second current-limiting unit 321″ and I/O interface unit 33 are electrically connected to the second isolation unit 323″, the third filter unit 322″ is electrically connected to the second current-limiting unit 321″ and the fourth filter unit 324″ and the second isolation unit 323″ are electrically connected to the micro-processor. In this Embodiment, the second current-limiting unit 321″ comprises the seventh resistor R7. The first end of the seventh resistor R7 is electrically connected to the I/O interface unit 33 and the second end of the seventh resistor R7 is electrically connected to the second isolation unit 323″. The third filter unit 322″ comprises the third capacitor C3. The first end of the third capacitor C3 is electrically connected to the I/O interface unit 33 and the second end of the third capacitor C3 is electrically connected to the second end of the seventh resistor R7. The fourth filter unit 324″ comprises the fourth capacitor C4. The first end of the fourth capacitor C4 and the second isolation unit 323″ are electrically connected to the microprocessor and the second end of the fourth capacitor C4 is grounded. In this Embodiment, there are several of the second current-limiting unit 321″, the third filter unit 322″ the second isolation unit 323″ and the fourth filter unit 324″. This can be understood that the quantity of the second current-limiting unit 321″, the third filter unit 322″ the second isolation unit 323″ and the fourth filter unit 324″ can be set as needed, so this is not specifically defined here. The low-speed signal input processing circuit 32″ of this Embodiment has the advantage of a simple structure.

The low-speed differential output signal processing circuit 33″ comprises the third current-limiting unit 331″, the third isolation unit 332″ and the first signal-amplifying unit 333″. The third current-limiting unit 331″ is electrically connected to the third isolation unit 332″ and the first signal-amplifying unit 333″ is electrically connected to the third isolation unit 332″. In this Embodiment, the third current-limiting unit 331″ comprises the eighth resistor R8. The first end of the eighth resistor R8 is connected to the first power supply and the second end of the eighth resistor R8 is electrically connected to the third isolation unit 332″. The first signal-amplifying unit 333″ comprises the first triode Q1, the second diode D2 and the ninth resistor R9. The base electrode of the first triode Q1 is electrically connected to the third isolation unit 332″, the emitter electrode of the first triode Q1 is electrically connected to the I/O interface unit 33 and the collector electrode of the first triode Q1 and the third isolation unit 332″ are electrically connected to the I/O interface unit 33. The anode of the second diode D2 is electrically connected to the emitter electrode of the first triode Q1 and the cathode of the second diode D2 is electrically connected to the collector electrode of the first triode Q1. The first end of the ninth resistor R9 is mutually connected to the base electrode of the first triode Q1 and the second end of the ninth resistor R9 is electrically connected to the emitter electrode of the first triode Q1. Its signal transmission is stable and reliable.

The low-speed single-ended output signal processing circuit 34″ comprises the fourth current-limiting unit 341″, the fourth isolation unit 342″ and the second signal amplifying unit 343″. The fourth current-limiting unit 341″ is electrically connected to the fourth isolation unit 342″ and the second signal-amplifying unit 343″ is electrically connected to the fourth isolation unit 342″. In this Embodiment, the fourth current-limiting unit 341″ comprises the tenth resistor R310. The first end of the tenth resistor R310 is connected to the first power supply and the second end of the tenth resistor R310 is electrically connected to the fourth isolation unit 342″. The second signal-amplifying unit 343″ comprises the second triode Q2, the third diode D3 and the eleventh resistor R31. The base electrode of the second triode Q2 is electrically connected to the fourth isolation unit 342″, the emitter electrode of the second triode Q2 is electrically connected to the I/O interface unit 33 and the collector electrode of the second triode Q2 and the fourth isolation unit 342″ are electrically connected to the I/O interface unit 33. The anode of the third diode D3 is electrically connected to the emitter electrode of the second triode Q2 and the cathode of the third diode D3 is electrically connected to the collector electrode of the second triode Q2. The first end of the eleventh resistor R31 is mutually connected to the base electrode of the second triode Q2 and the second end of the eleventh resistor R31 is electrically connected to the emitter electrode of the second triode Q2. In this Embodiment, there are several fourth current-limiting units 341″, fourth isolation units 342″ and second signal-amplifying units 343″. It can be understood that the quantity of the fourth current-limiting unit 341″, the fourth isolation unit 342″ and the second signal-amplifying unit 343″ may be set as needed, so this is not specifically defined here.

This Embodiment also disclosed a drive device, which comprises: a motor and the stepper motor driver shown in the various said embodiments. The structure of the stepper motor driver of this Embodiment is the same as the stepper motor drivers shown in the various said embodiments, so it has the same technical effect.

This Embodiment also disclosed an automation device, which comprises: the drive device in the said Embodiment. The structure of the drive device in this Embodiment is the same as the drive device in the said embodiments, so it has the same technical effect.

The preferred embodiments above describe the purpose, technical solution and advantages of the present invention in detail. The description of the above embodiments are only to facilitate an understanding of the methods and core ideas of the present invention. At the same time, based on the ideas of the present invention, there may be changes to the specific embodiment methods and scope of application by those of ordinary skill in the art. In addition, the “first,”“second” and similar terms used in the present invention do not represent any order, quantity or significance, and are only used to differentiate different objects. In conclusion, the content of this Specification only describes the embodiment methods of the present invention and shall not restrict the protection scope of the patent of the present invention. All equivalent structures or equivalent process transformations based on the specification and drawings of the present invention, or direct or indirect applications thereof in other relevant technical fields shall be similarly covered by the protection scope of the patent of the present invention. This shall not be construed as a restriction of the present invention.

1. A stepper motor driver with brake drive, wherein it comprises a microprocessor embedded with a communication protocol, an external interface unit mutually connected to the said microprocessor and a communication interface circuit; the said microprocessor is also connected to a drive control circuit and brake device, and the said brake device is mutually connected to the said external interface unit; the said microprocessor is also mutually connected to a power supply circuit that provides a stable power supply voltage.

2. The stepper motor driver with brake drive as claimed in claim 1, wherein the said brake device comprises a brake drive circuit and brake; the said brake drive circuit comprises an isolation unit and amplifier, the said microprocessor is connected to the said amplifier through the said isolation unit and the said amplifier is used to amplify the current signal output by the said isolation unit, sending it to the said brake.

3. The stepper motor driver with brake drive as claimed in claim 2, wherein the said isolation unit, the said amplifier and the said microprocessor are installed on the same circuit substrate.

4. The stepper motor driver with brake drive as claimed in claim 2, wherein the said brake drive circuit also comprises a switch unit and the said switch unit is connected in series to the said amplifier.

5. The stepper motor driver with brake drive as in claim 2, wherein the said brake drive circuit also comprises: a protection unit. One end of the said protection unit is connected to the said amplifier and the other end is connected to the input end of the power supply of the said brake.

6. The stepper motor driver with brake drive as in claim 2, wherein the said external interface comprises a power supply interface unit, winding interface unit, and I/O interface unit; the said power supply interface unit is mutually connected to the said power supply circuit; one end of the said winding interface unit is mutually connected to the said drive control circuit and the other end is mutually connected to the stepper motor; the said I/O interface unit is mutually connected to the said microprocessor.

7. The stepper motor driver with brake drive as claimed in claim 6, wherein the said I/O interface unit comprises: the first output interface, the second output interface, and the third output interface; the said first output interface is used to connect to the first end of the said brake, the said second output interface is used to connect to the second end of the brake, and the said third output interface is used to connect to the power supply grounding end of the said brake.

8. The stepper motor driver with brake drive as in claim 1, wherein the said communication interface circuit comprises a physical layer communication circuit and anti-interference circuit. The said anti-interference circuit is electrically connected to the said microprocessor through the said physical layer communication circuit.

9. The stepper motor driver with brake drive as claimed in claim 8, wherein the said anti-interference circuit comprises the first common mode choke and first transient voltage suppressor. The said first transient voltage suppressor is connected to one end of the said first common mode choke.

10. The stepper motor driver with brake drive as claimed in claim 9, wherein the said anti-interference circuit is connected to the first transformer. The said first transformer is electrically connected to the said first common mode choke and the said first transformer is used to send the signal sent from the said first common mode choke to the said microprocessor.

11. The stepper motor driver with brake drive as in claim 1, wherein the said stepper motor driver with brake drive also comprises a communication address setting circuit, and the said communication address setting circuit is mutually connected to the said microprocessor; of which, the said communication address setting circuit is a DIP switch.

12. The stepper motor driver with brake drive as in claim 1, wherein the said stepper motor driver with brake drive also comprises a display unit and the said display unit is electrically connected to the said microprocessor; of which, the said display unit comprises one or several of the following types: LED indicator light, digital tube and liquid crystal display.

13. The stepper motor driver with brake drive as in claim 1, wherein the said stepper motor driver with brake drive also comprises an alarm unit, and the said alarm unit is electrically connected to the said microprocessor.

14. A drive device, comprising a motor, wherein the said drive device comprises the stepper motor driver with brake drive as claimed in claim 1.

15. An automation device, wherein it comprises the drive device claimed in claim 14.
